(19) United States
(12) Patent Application Publication
(10) Pub. No.: US 2024/0080988 A1
(43) Pub. Date: Mar. 7, 2024

(54) HIGH DENSITY INTERPOSERS WITH MODULAR MEMORY UNITS

(71) Applicant: Intel Corporation, Santa Clara, CA (US)

(72) Inventors: Todd A. HINCK, Arlington, MA (US); Michael T. CROCKER, Portland, OR (US); Xiang LI, Portland, OR (US); Vijaya K. BODDU, Pleasanton, CA (US)

(21) Appl. No.: 18/506,951

(22) Filed: Nov. 10, 2023

(51) Int. Cl. H05K 1/18; H05K 1/02; H05K 7/14

(52) U.S. Cl. CPC H05K 1/181; H05K 1/0209; H05K 7/1429; H05K 2201/10159; H05K 2201/10378

(57) ABSTRACT

A system includes a processor, such as a CPU, surrounded by high-density memory with lower profile than a standard DIMM. The low profile, high-density memory provides multiple memory channels for the processor. With the memory configuration, the system can maintain the memory configurability with increased density and increased memory channels for the processor.

### FIELD

Descriptions are generally related to computer systems, and more particular descriptions are related to systems with processors and memory.

### BACKGROUND

Memory systems employ a variety of form factors to connect memory modules, such as DIMMs (dual inline memory modules), or memory packages to a host system that has the processor. Server systems currently use DIMMs, which orient memory packages orthogonal to the server baseboard. As server systems have grown in core count, so has the demand for memory for each of the processors, such as a CPU (central processing unit). Increased memory demand has increased the demand for memory channels, which increases the pin count in the host system. Larger memory channels and higher pins counts result in a memory electrical channel that is more complex in terms of crosstalk and channel routing.

There is a limit to the number of DIMM memory channels available in server systems, currently a 19-inch server platform board is limited to 12 memory channels in a 2-socket spread core design. Likewise, a 21″ server platform is limited to 16 memory channels in a 2-socket spread core design. In such systems, the DIMMs are arranged on the side of the CPU with the DIMM aligned orthogonal to the platform fans. In addition to the limit on the number of channels, the DIMM alignment limits the thermal performance of the system with respect to the memory.

### BRIEF DESCRIPTION OF THE DRAWINGS

The following description includes discussion of figures having illustrations given by way of example of an implementation. The drawings should be understood by way of example, and not by way of limitation. As used herein, references to one or more examples are to be understood as describing a particular feature, structure, or characteristic included in at least one implementation of the invention. Phrases such as “in one example” or “in an alternative example” appearing herein provide examples of implementations of the invention, and do not necessarily all refer to the same implementation. However, they are also not necessarily mutually exclusive.

FIG. 1 is a block diagram of an example of a system with high-density memory.

FIG. 2 is a block diagram of an example of a system with CAMM memory mounted by a processor.

FIGS. 3A-3D are block diagrams of examples of a CAMM device.

FIGS. 4A-4B are block diagrams of an example of a system with multiple memory channels.

FIGS. 5A-5C are block diagrams of an example of a sideview of a system with memory modules coupled close to the processor on an interposer with a socket connector.

FIG. 5D is a block diagram of an example of a sideview of a system with memory modules coupled close to the processor on an interposer with a mezzanine connector.

FIG. 6A is a block diagram of an example of a system with 24 memory channels.

FIG. 6B is a block diagram of an example of a system with 32 memory channels.

FIG. 7 is a block diagram of an example of a system with 16 high-capacity memory channels.

FIG. 8A is a block diagram of an example of a system with 32 memory channels close to a processor.

FIG. 8B is a block diagram of an example of a system with 64 memory channels surrounding a processor.

FIG. 9 is a block diagram of an example of a system with four interposers having 1 processor and 16 memory channels each.

FIG. 10 is a block diagram of an example of a system with eight interposers having 1 processor and 16 memory channels each.

FIG. 11 is a block diagram of an example of a memory subsystem in which a high density memory configuration can be implemented.

FIGS. 12A-12B are block diagrams of an example of a CAMM system for a high density memory configuration.

FIG. 13 is a block diagram of an example of a computing system in which a high density memory configuration can be implemented.

FIG. 14 is a block diagram of an example of a multi-node network in which a high density memory configuration can be implemented.

Descriptions of certain details and implementations follow, including non-limiting descriptions of the figures, which may depict some or all examples, and well as other potential implementations.

### DETAILED DESCRIPTION

As described herein, a system has high-density memory around a processor, such as a CPU (central processing unit) or GPU (graphics processing unit). The memory is compression-attached memory with a lower profile compared to a standard DIMM (dual inline memory module). The low profile, high-density memory provides multiple memory channels for the processor. With the memory configuration, the system can maintain the memory configurability available with DIMM configurations, with increased density and increased memory channels for the processor.

Memory in server systems is currently implemented with DIMMs oriented orthogonal to the server baseboard. Mobile systems use lower profile memory packages, but cannot provide the number of memory channels needed for server systems. As described herein, a server memory system has memory modules located physically close to the processor with short memory channels. Even with the short memory channels and the memory close to the processor, the system can maintain the requirements that a server system has for memory, such as modularity, configurability for high channel count, and high bandwidth and high capacity like a current DIMM.

In one example, the processor is disposed on an interposer board. In one example, the processor is first disposed on an SOC (system on a chip) and then on an interposer. The memory packages can be disposed on the interposer board with the processor/SOC, with short memory channels. In one example, with the processor on an interposer, the system can be implemented without a socket, with an interposer board material better adapted to memory channel signaling as opposed to being optimized for SERDES (serialization/deserialization) as with typical system baseboards. With such an interposer adapted for memory channel signaling, the system can further reduce the memory channel distance, as well as reducing crosstalk.

In one example, the system implements the memory with CAMMs (compression attached memory modules), which are compressibly attached to the processor interposer. The compression attachment enables the memory to be removable and upgradeable. CAMM modules orient the memory devices parallel with the system board or baseboard, instead of orthogonally with DIMM modules. The configuration of the CAMMs provides flat memory modules that allow for improved cooling solutions. The flat CAMM modules can have a vertical height similar or the same as the processor, allowing for a single heat sink or cold plate to lay over the processor and the multiple memory channels.

The high density CAMM modules have more pins and more channels connected to the processor as compared to DIMM modules. The system allows shorter channel length between the memory and the processor. Using an interposer allows the system to have more pins out. The processor can be directly soldered to the interposer board with a BGA (ball grid array) connector side of the processor.

The system creates a memory channel that is electrically better than use of DIMMs with a socket, while retaining the modularity of memory systems using DIMMs. The low profile CAMM form factor allows for higher memory channel count, with at least two times more memory channels, while still allowing the system to provide a 2-socket spread core within a 19″ rack. The system provides a more optimal memory cooling form factor. The flat memory module allows for a heat sink or cooling plate to cover multiple memory channels and a processor.

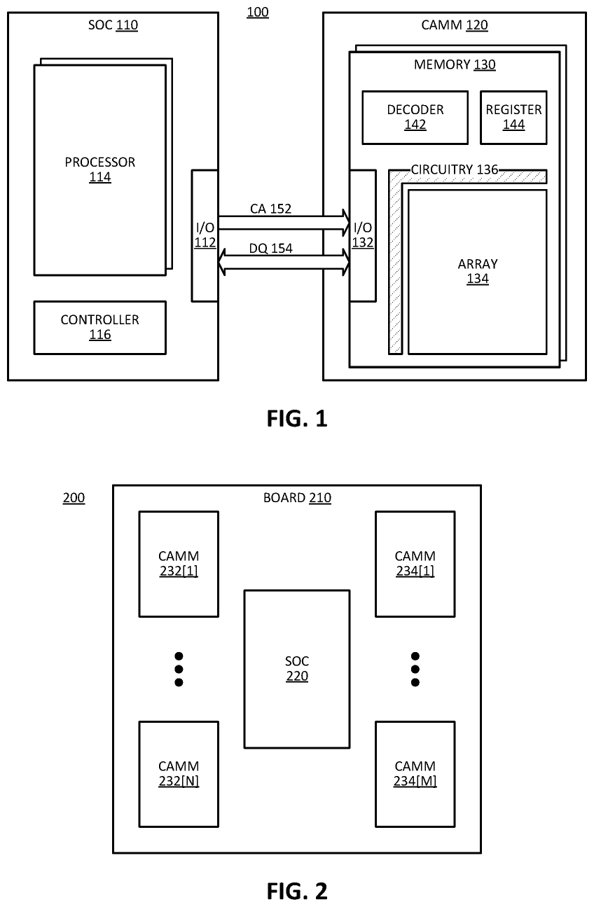

FIG. 1 is a block diagram of an example of a system with high-density memory. System 100 includes SOC (system on a chip) 110 with processor 114 and controller 116. Controller 116 can be a memory controller. In one example, controller 116 is an iMC (integrated memory controller), which is integrated on the processor die.

System 100 includes memory 130 disposed on CAMM (compression attached memory) 120. Memory 130 includes array 134, which represents a memory array. Memory 130 includes decoder 142 to decode commands and register 144 to store configuration information. In one example, register 144 is a mode register.

Memory 130 includes circuitry 136 to manage access to array 134. Circuitry 136 can include column decode circuitry to manage access to specific columns and bits of memory, as well as row decode circuitry to manage access to selected rows of memory.

I/O (input/output) 112 represents a hardware interface of SOC 110 to couple to I/O (input/output) 132 of memory 130. The interface includes CA (command/address) 152, which represents signal lines for a command and address bus. The CA bus is a unidirectional bus from controller 116 to memory 130. The interface includes DQ (data) 154, which represents signal lines for a data bus. The DQ bus is a bidirectional bus allowing SOC 110 and memory 130 to exchange data with each other.

In one example, system 100 includes CAMMs that are located close to SOC 110 with short memory channels. The short memory channels refer to short physical distances for CA 152 and DQ 154 between SOC 110 and CAMM 120.

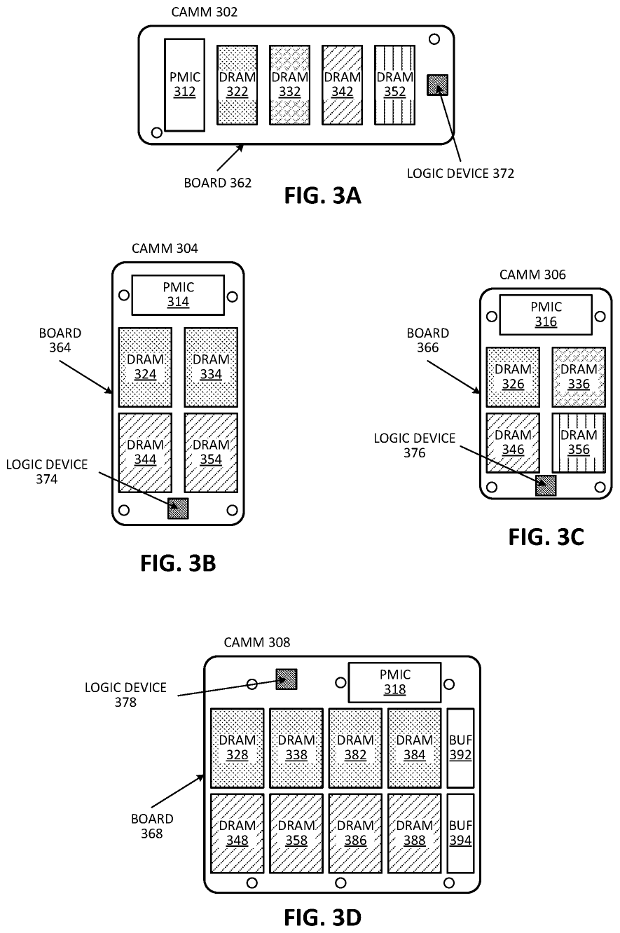

FIG. 2 is a block diagram of an example of a system with CAMM memory mounted by a processor. System 200 provides an example of system 100. System 200 shows a two-dimensional top view of a system layout.

System 200 includes board 210, which represents an interposer board, which can be connected to a system baseboard or system motherboard. The material and structure of board 210 can be selected for the placement of CAMMs close to the SOC.

Board 210 includes SOC 220, which can represent a system on a chip with a processor die, or can represent the processor die itself disposed on board 210. In one example, SOC 220 represents a CPU system. In one example, SOC 220 represents a GPU system. In one example, SOC 220 represents an AI (artificial intelligence) processor system.

System 200 illustrates CAMMs 232[1:N], collectively CAMMs 232, and CAMMs 234[1:N], collectively CAMMs 134. CAMMs 232 and CAMMs 234 are illustrated as separate columns of memory devices surrounding SOC 220. It will be understood that the various CAMMs can include memory devices coupled to multiple separate memory channels. A memory channel refers to a collection of memory devices accessed in parallel. Each memory channel provides access to its group of memory devices separately from the memory devices of a different memory channel. Thus, the memory channels provide memory access independent of each other.

CAMMs 232 and CAMMs 234 represent memory modules that are removably attached via compression attachment. Compression attachment uses screws or other securing mechanism to compress module contacts to contacts on board 210. Releasing the securing mechanism allows removing and exchanging the CAMMs, as opposed to soldering the modules to the board. SOC 220 or the processor can be soldered to board 210.

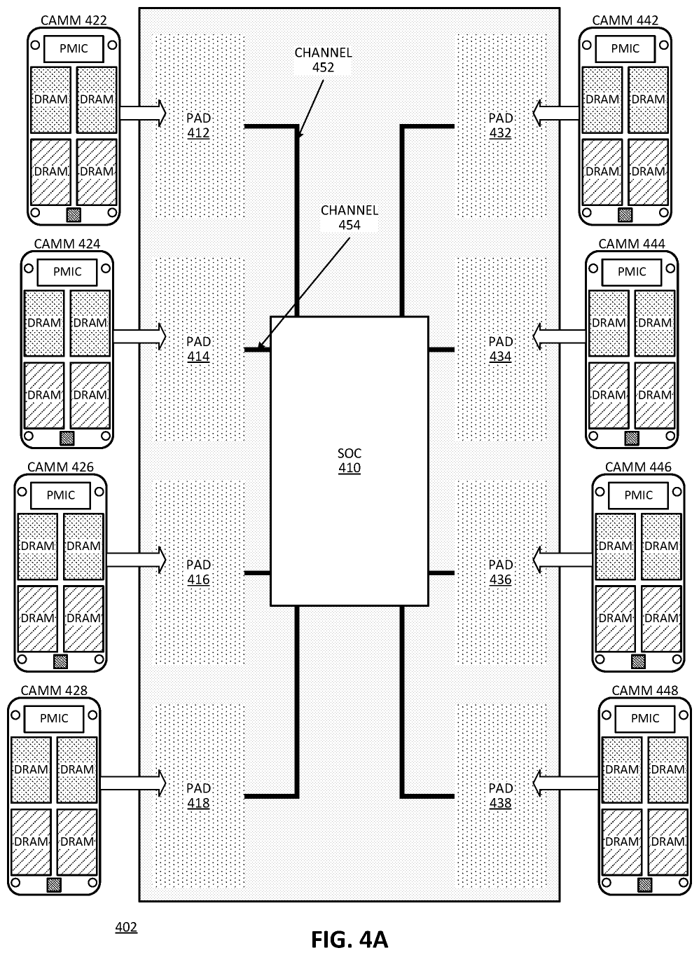

FIGS. 3A-3D are block diagrams of examples of a CAMM device. The required memory system will have requirements for capacity, speed, and RAS (reliability, accessibility, and serviceability) which can be used to determine how many memory dies and memory packages should be included per memory channel. The system architecture can employ memory modules that allow for a compact interposer architecture with the desired number of channels, desired number of memory devices per channel, and how many CAMMs can be used to provide the memory devices.

FIG. 3A illustrates a CAMM module with four memory channels, each channel only having one memory package. CAMM 302 represents one implementation of a CAMM, having board 362 with DRAM 322, DRAM 332, DRAM 342, and DRAM 352 disposed on it. The DRAMs of CAMM 302 are different shading, indicating that they are part of different memory channels. CAMM 302 also includes PMIC (power management integrated circuit) 312 and logic device 372. The logic device can be, for example, a registering clock driver (RCD), a clock driver, an SPD (serial presence detect) with hub function, or other logic device.

FIG. 3B illustrates a CAMM module with two memory channels, each channel having two memory packages. CAMM 304 represents one implementation of a CAMM, having board 364 with DRAM 324, DRAM 334, DRAM 344, and DRAM 354 disposed on it. DRAM 324 and DRAM 334 are part of one memory channel, and DRAM 344 and DRAM 354 are part of another memory channel. CAMM 304 also includes PMIC 314 and logic device 374.

FIG. 3C illustrates a CAMM module with four memory channels, each channel only having one memory package. CAMM 306 represents one implementation of a CAMM, having board 366 with DRAM 326, DRAM 336, DRAM 346, and DRAM 356 disposed on it. The DRAMs of CAMM 306 are different shading, indicating that they are part of different memory channels. CAMM 306 also includes PMIC 316 and logic device 376.

FIG. 3D illustrates a CAMM module with two memory channels, each channel having four memory packages. CAMM 308 represents one implementation of a CAMM, having board 368 with DRAM 328, DRAM 338, DRAM 348, DRAM 358, DRAM 382, DRAM 384, DRAM 386, and DRAM 388 disposed on it. DRAM 328, DRAM 338, DRAM 382, and DRAM 384 are part of one memory channel, and DRAM 348, DRAM 358, DRAM 386, and DRAM 388 are part of another memory channel. CAMM 308 also includes PMIC 318 and logic device 378.

In one example, the first channel has BUF (buffer) 392, and the second channel has BUF (buffer) 394. Buffer 392 and buffer 394 buffer data for their respective channels. The buffers can be useful because of having the four memory devices per channel per CAMM.

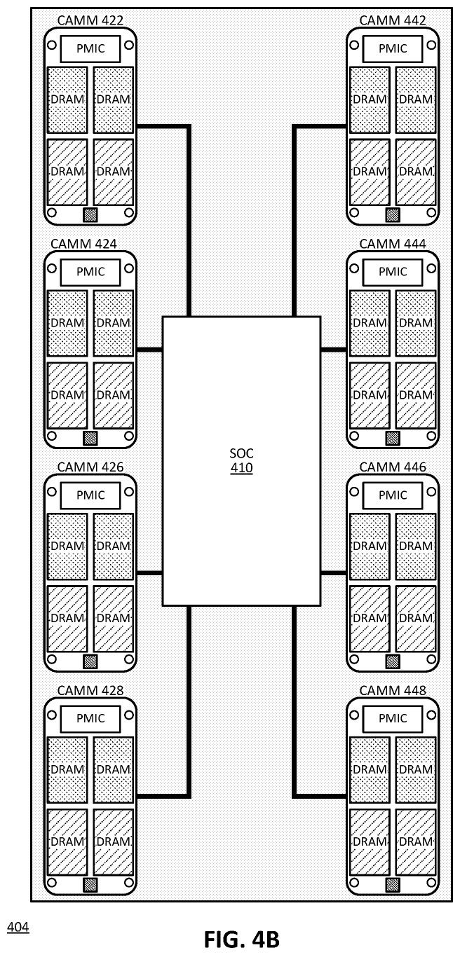

FIG. 4A is a block diagram of an example of a system with multiple memory channels. System 402 includes SOC 410 disposed on an interposer board. SOC 410 represents a system on a chip that can be or include a CPU or a GPU. In one example, SOC 410 can include at least one CPU or at least one GPU, as well as including accelerators, such as an AI accelerator device.

System 402 is configured to have multiple CAMMs removably attached with compression to the board around SOC 410. The details of the CAMMs are not specifically described, but they include DRAM devices and supporting circuitry.

The board has pad locations on either side of SOC 410, illustrated as pad 412, pad 414, pad 416, and pad 418 on one side (the left side of the view as illustrated), and pad 432, pad 434, pad 436, and pad 438 on the other side. In system 402, CAMM 422 will be disposed on pad 412, CAMM 424 will be disposed on pad 414, CAMM 426 will be disposed on pad 416, CAMM 428 will be disposed on pad 418, CAMM 442 will be disposed on pad 432, CAMM 444 will be disposed on pad 434, CAMM 446 will be disposed on pad 436, and CAMM 448 will be disposed on pad 438.

System 402 illustrates a memory subsystem for an SOC/CPU can be implemented with memory modules placed on an interposer structure. The SOC/CPU can be attached to the interposer board via solder or other BGA bonding. Several memory modules are placed around the SOC/CPU. In one example, SOC 410 is centered on the interposer board with the memory modules around it. In one example, SOC 410 is off-center on the interposer board with the memory modules around it. The number of memory modules can be different depending on the system usage and requirements. In one example, the memory modules are soldered down to the interposer structure. In one example, the memory modules are connectorized to the interposer structure.

In one example, in system 402, each memory module is attached using a compression connector to allow memory modules to be installed post interposer assembly and serviced in the field if needed. The board technology of the interposer board can be designed with low crosstalk and short channel lengths for the memory channels from SOC 410 to the memory packages (i.e., the CAMMs illustrated). System 402 illustrates channel 452 to connect CAMM 422 through pad 412 to SOC 410, and channel 454 to connect CAMM 424 through pad 414 to SOC 410.

System 402 illustrates eight CAMMs, each with four DRAMs, with two DRAMs per channel. The two DRAMs per channel are illustrated by the same shading in the two pairs of DRAMs per CAMM. Thus, system 402 illustrates a 16-channel interposer with SOC 410. System 402 illustrates all memory modules mounted to the same side of the interposer board as SOC 410. In one example, the interposer board can have memory modules on both sides of the interposer board.

The memory module can have any number of different shapes and sizes. The different examples of FIGS. 3A-3D are not exhaustive of the types of size and shape. A memory module can have 1, 2, 3, 4, or more memory channels per CAMM, depending on the application.

FIG. 4B is a block diagram of an example of the system of FIG. 4A. System 404 represents an example of system 402 with the CAMMs mounted to the interposer board.

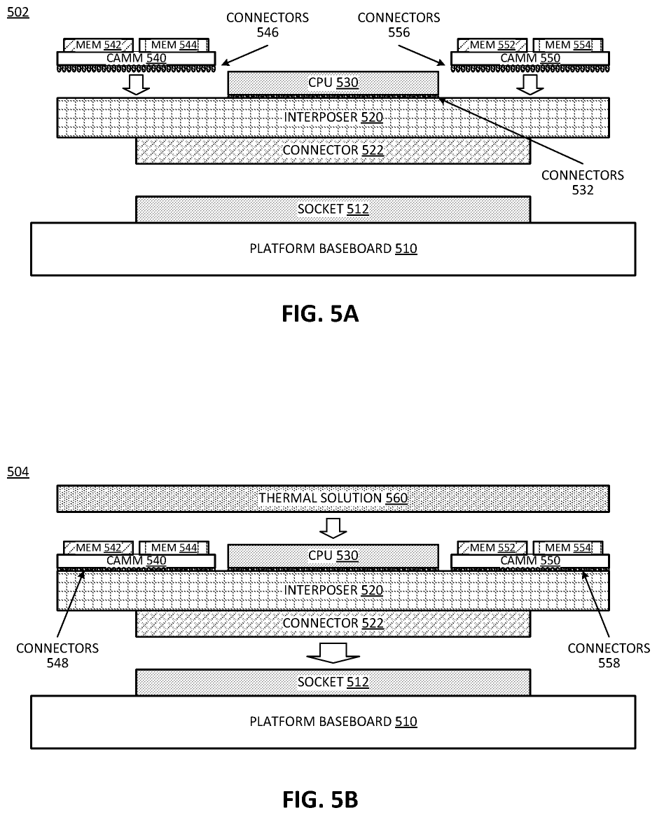

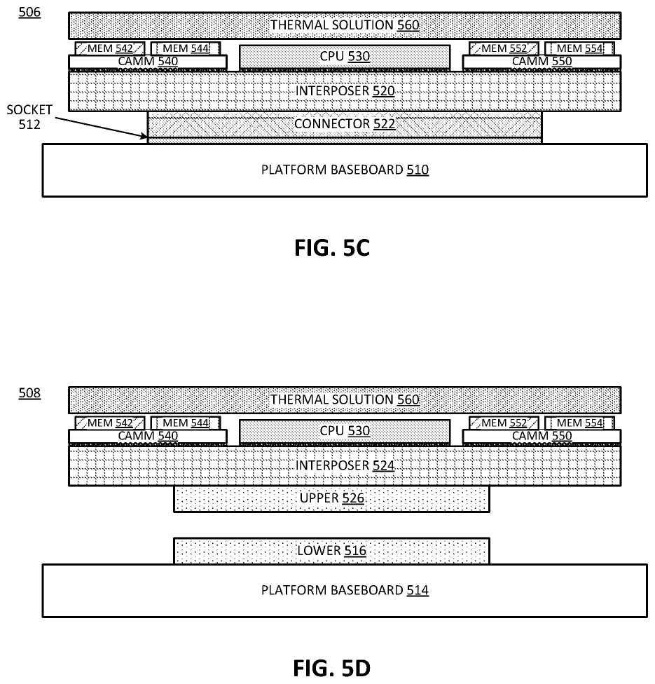

FIG. 5A is a block diagram of an example of a sideview of a system with memory modules coupled close to the processor on an interposer with a socket connector.

System 502 illustrates an example of an interposer system. Other interposer systems can be implemented that have different interposer designs or layouts, which also allow for close disposition of the memory modules to the SOC/CPU.

System 502 illustrates platform baseboard 510, which represents a system board. Platform baseboard 510 is the board to which the processor and memory combination is mounted, and can be referred to as a system board or a motherboard. In one example, platform baseboard 510 is a board that will be connected into a rack connector. In one example, platform baseboard 510 includes socket 512 to receive the processor interposer board.

System 502 includes interposer 520 having connector 522. Connector 522 represents a connector mechanism to interface with socket 512. When connector 522 is inserted into socket 512, it provides a connection of signal lines on platform baseboard 512 to components mounted on interposer 520. CPU 530 represents a processor for system 502, and a different type of processor or processor SOC can be used. In one example, CPU 530 is soldered down on interposer 520, as a non-socket CPU. Alternatively, interposer 520 can have a socket for CPU 530.

System 502 includes CAMM 540 and CAMM 550, which represent memory modules for the memory subsystem of CPU 530. CAMM 540 includes MEM (memory) 542 and MEM (memory) 544, which represent memory devices (e.g., DRAMs) for the memory subsystem. CAMM 540 includes connectors 546 on a surface of the CAMM board that is to interface with interposer 520. In one example, connectors 546 represent compression connectors. Compression connectors refer to connectors that change shape in response to a compressive force. The change of shape can be, for example, a ‘C’ shaped connector that compresses under tension.

CAMM 550 includes MEM (memory) 552 and MEM (memory) 554, which represent memory devices for the memory subsystem. CAMM 550 includes connectors 556 on the bottom surface of the CAMM board, opposite the side on which the memory devices are mounted. In one example, connectors 556 represent compression connectors.

FIG. 5B is a block diagram of an example of a sideview of the system of FIG. 5A with the CAMMs mounted to the interposer board. System 504 illustrates an example of system 502 with CAMM 540 and CAMM 550 mounted to interposer 520. In one example of system 504, connectors 546 and connectors 556 are compressed, and are thus illustrated as connectors 548 and connectors 558, respectively. Connectors 548 and connectors 558 represent compressed connectors.

In one example, system 504 includes thermal solution 560. Thermal solution 560 can be a thermal plate, cold plate, a heat sink, a cooling system, or other thermal solution to disperse heat from CPU 530 and the memory devices. In one example, thermal solution 560 can be a single plate or a single structure. In one example, thermal solution 560 is implemented with multiple plates or multiple structures. As illustrated, the vertical height of the CAMMs with their memory devices is the same or comparable to the vertical height of CPU 530. To the extent there is a difference in vertical height, a thermal conductor or an additional mechanical component can be added to improve thermal conductivity between the components of interposer 520 and thermal solution 560.

FIG. 5C is a block diagram of an example of a sideview of the system of FIG. 5B with the interposer board mounted to the system board. System 506 illustrates an example of system 504 with connector 522 mounted in socket 512, and thermal solution 560 mounted over interposer 520. In one example, system 506 includes another interposer that is not specifically illustrated. In such an example, thermal solution 560 can cover both interposer 520 as well as the other interposer. Thus, thermal solution 560 can be a thermal solution for a CPU and multiple memory channels, or multiple CPUs each with multiple memory channels.

FIG. 5D is a block diagram of an example of a sideview of a system with memory modules coupled close to the processor on an interposer with a mezzanine connector. System 508 illustrates an example of system 504, and instead of connector 522 on interposer 520, system 508 illustrates interposer 524 with an upper mezzanine connector, upper 526. Similarly, system 508 illustrates platform baseboard 504 with a lower mezzanine connector, lower 516, which is to interface with upper 526. Thus, the interposer can be configured to mount to the system board via a connector and socket, via a mezzanine connector, or directly to the system board with a socket. The direct connection without a socket is not specifically illustrated.

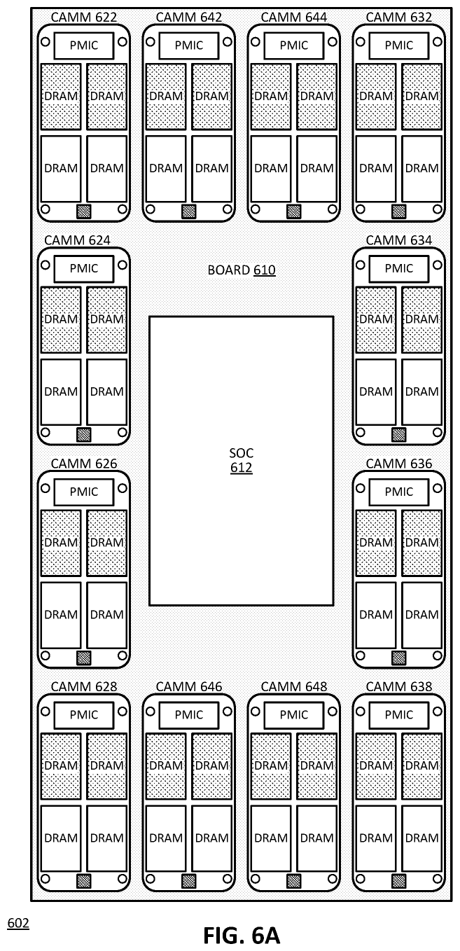

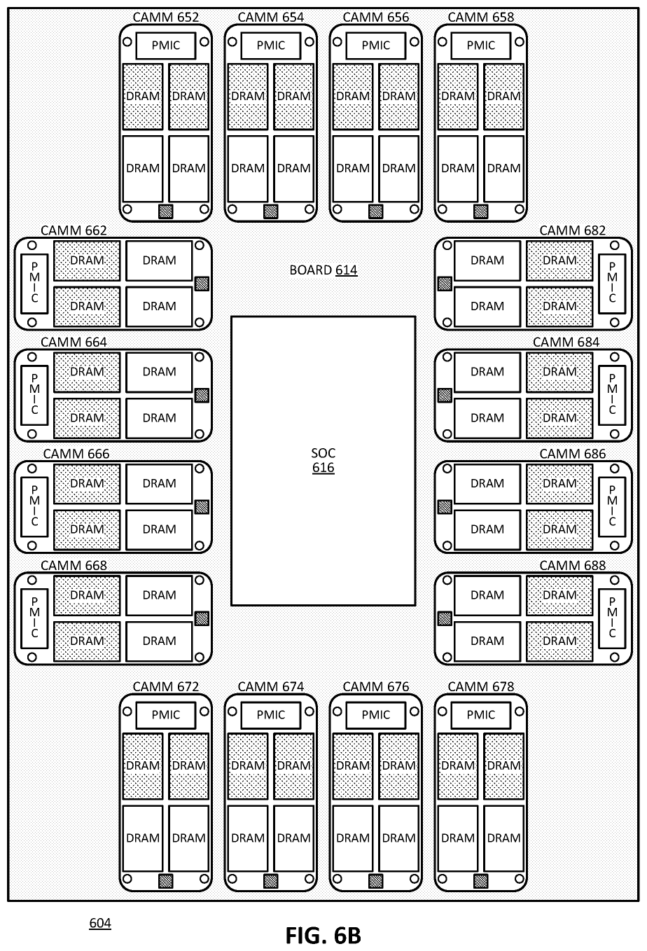

FIG. 6A is a block diagram of an example of a system with 24 memory channels. System 602 illustrates SOC 612 mounted on interposer board 610, with SOC 612 completely surrounded by CAMMs. System 602 illustrates CAMM 622, CAMM 624, CAMM 626, CAMM 628, CAMM 632, CAMM 634, CAMM 636, CAMM 638, CAMM 642, CAMM 644, CAMM 646, and CAMM 648 mounted to board 610 around SOC 612.

Each of the CAMMs represents a two-channel memory module with two packages per channel. The twelve CAMMs means that system 602 represents a system with 24 memory channels for the processor.

FIG. 6B is a block diagram of an example of a system with 32 memory channels. System 604 illustrates SOC 616 mounted on interposer board 614, with SOC 616 completely surrounded by CAMMs. System 606 illustrates CAMM 652, CAMM 654, CAMM 656, CAMM 658, CAMM 662, CAMM 664, CAMM 666, CAMM 668, CAMM 672, CAMM 674, CAMM 676, CAMM 678, CAMM 682, CAMM 684, CAMM 686, and CAMM 688 mounted to board 614 around SOC 616.

Each of the CAMMs represents a two-channel memory module with two packages per channel. The sixteen CAMMs means that system 604 represents a system with 32 memory channels for the processor. System 604 illustrates a system in which some memory modules are rotated 90 degrees relative to other memory modules.

Specifically illustrated, the CAMMs of system 604 are rectangular, with a length longer than the width. The CAMMs above and below SOC 616 are oriented with respect to the view of the page with the length top to bottom and the width left to right. The CAMMs on the left and right of SOC 616 are oriented with a 90-degree rotation relative to the CAMMs above and below SOC 616, where the CAMMs to the left and right have the length from left to right and the width from top to bottom. There can be any number of combinations of CAMMs oriented with different rotations.

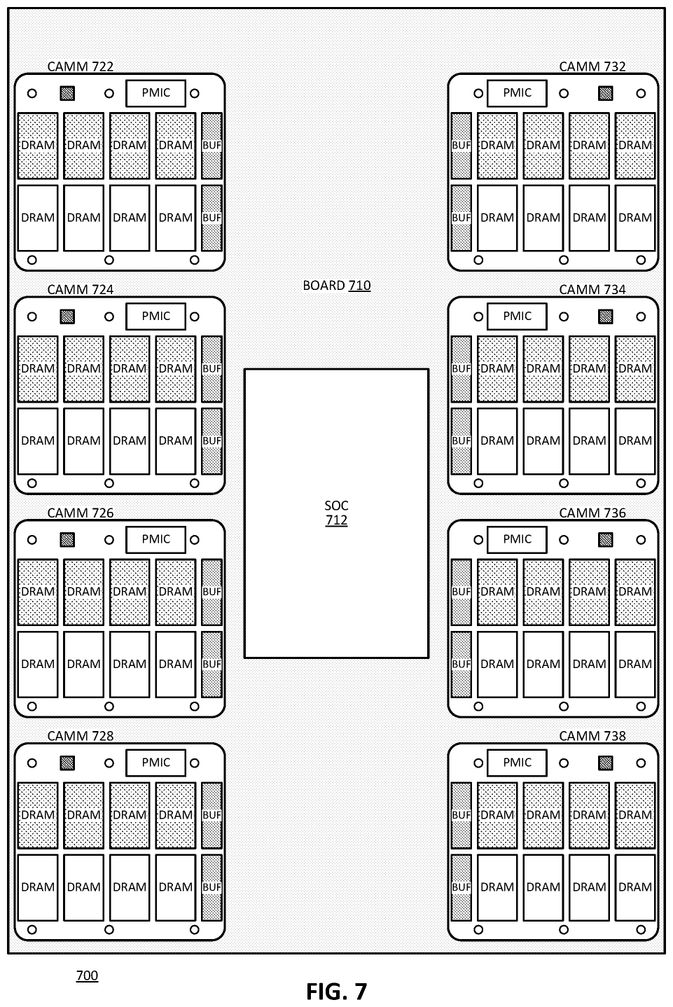

FIG. 7 is a block diagram of an example of a system with 16 high-capacity memory channels. System 700 illustrates SOC 712 mounted on interposer board 710, with memory modules on mounted to two sides of SOC 712. System 700 illustrates CAMM 722, CAMM 724, CAMM 726, CAMM 728, CAMM 732, CAMM 734, CAMM 736, and CAMM 738 mounted to board 710 around SOC 712.

Each of the CAMMs represents a two-channel memory module with four packages per channel. The eight CAMMs means that system 700 represents a system with 16 memory channels for the processor. The 16 memory channels have much higher capacity because each device has four memory devices per channel.

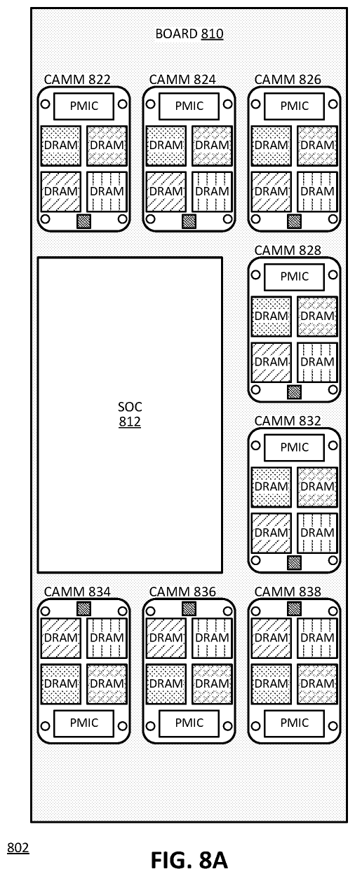

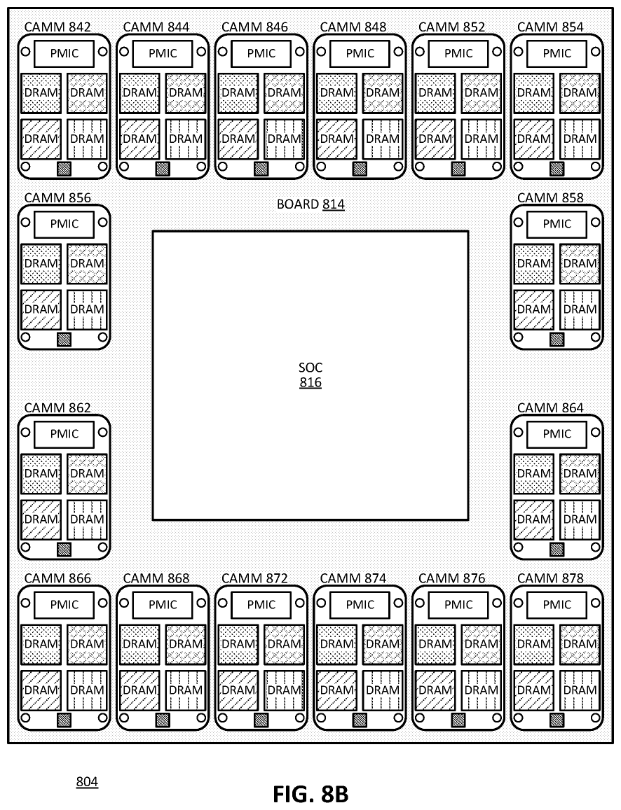

FIG. 8A is a block diagram of an example of a system with 32 memory channels close to a processor. System 802 illustrates SOC 812 mounted on interposer board 810, with SOC 812 surrounded by memory modules. More specifically, SOC 812 is not centered on board 810, and the memory modules are on three sides of SOC 812, leaving one side of the SOC open with respect to the memory modules. System 802 illustrates CAMM 822, CAMM 824, CAMM 826, CAMM 828, CAMM 832, CAMM 834, CAMM 836, and CAMM 838 mounted to board 810 around SOC 812.

Each of the CAMMs represents a four-channel memory module with one package per channel. The eight CAMMs means that system 802 represents a system with 32 memory channels for the processor. System 802 has channels with lower capacity than other system configurations because each module only has one memory device per channel.

FIG. 8B is a block diagram of an example of a system with 64 memory channels surrounding a processor. System 804 illustrates SOC 816 mounted on interposer board 814, with SOC 816 surrounded by memory modules. System 804 illustrates CAMM 842, CAMM 844, CAMM 846, CAMM 848, CAMM 852, CAMM 854, CAMM 856, CAMM 858, CAMM 862, CAMM 864, CAMM 866, CAMM 868, CAMM 872, CAMM 874, CAMM 876, and CAMM 878 mounted to board 814 around SOC 816.

Each of the CAMMs represents a four-channel memory module with one package per channel. The 16 CAMMs means that system 802 represents a system with 64 memory channels for the processor. While various system configurations herein can be used for different server systems, the high number of memory channels of system 804 can be better suited for AI applications, which benefit from increased ability to access memory in parallel.

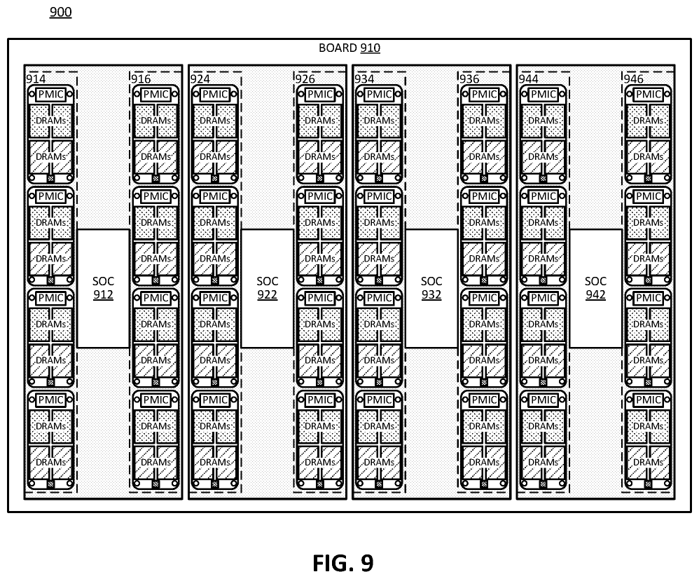

FIG. 9 is a block diagram of an example of a system with four interposers having 1 processor and 16 memory channels each. System 900 represents a system in which multiple interposer boards, each with a processor and multiple memory modules with many memory channels, are disposed on a common system baseboard. In one example, board 910 represents a board for a 19″ rack. In one example, board 910 represents a board for a 21″ rack.

Instead of a typical 2-socket spread core with multiple DIMMs, system 900 can include four SOCs, each with 16 memory channels. As described above, the interposer board can support a variety of channel configurations. System 900 illustrates a simple 16-channel configuration of interposer boards, each with eight CAMMs having two channels, with two memory packages per channel. It will be understood that system 900 could be adapted for different types of interposers with different channel configurations. It will be understood that different interposer configurations can limit how many will fit on board 910.

In system 900, a first interposer board includes SOC 912 with group 914 and group 916, each being groups of CAMMs. A second interposer board includes SOC 922 with group 924 and group 926, each being groups of CAMMs. A third interposer board includes SOC 932 with group 934 and group 936, each being groups of CAMMs. A fourth interposer board includes SOC 942 with group 944 and group 946, each being groups of CAMMs. In one example, each of the processor cores of SOC 912, SOC 922, SOC 932, and SOC 944 is a 96-core processor, with four total processors.

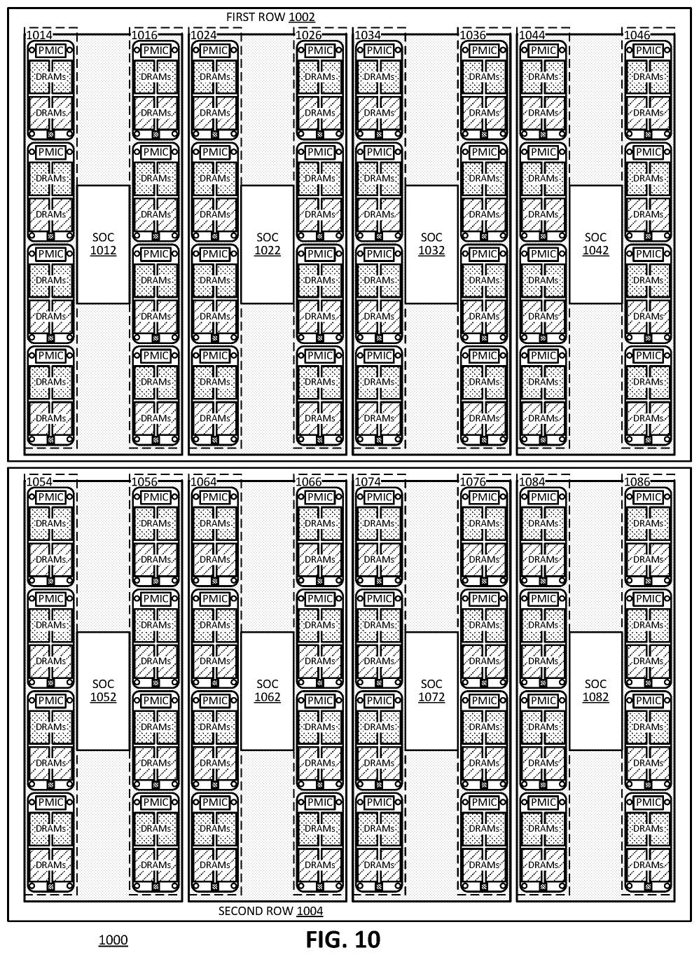

FIG. 10 is a block diagram of an example of a system with eight interposers having 1 processor and 16 memory channels each. System 1000 represents a system in which multiple interposer boards, each with a processor and multiple memory modules with many memory channels, are disposed on a common system baseboard. In one example, board 1010 represents a board for a 19″ rack. In one example, board 1010 represents a board for a 21″ rack.

System 1000 illustrates a system with two interposer boards on the system board. Relative to system 900, system 1000 adds a second row of SOCs in front of the first row. System 1000 can include four SOCs, each with 16 memory channels. In one example, system 1000 can have interposers on a back side of the system board. If the system board has interposers on both sides, there could be a potential issue with power density or with the application of a thermal solution. For these reasons, there may be some practicality issues in the application of certain possible implementations.

As described above, the interposer board can support a variety of channel configurations. System 1000 illustrates a simple 16-channel configuration of interposer boards, each with eight CAMMs having two channels, with two memory packages per channel. It will be understood that system 1000 could be adapted for different types of interposers with different channel configurations. It will be understood that different interposer configurations can limit how many will fit on board 1010.

In system 1000, first row 1002 has a first interposer board with SOC 1012 with group 1014 and group 1016, each being groups of CAMMs. First row 1002 has a second interposer board with SOC 1022 with group 1024 and group 1026, each being groups of CAMMs. First row 1002 has a third interposer board with SOC 1032 with group 1034 and group 1036, each being groups of CAMMs. First row 1002 has a fourth interposer board with SOC 1042 with group 1044 and group 1046, each being groups of CAMMs.

In system 1000, second row 1004 has a fifth interposer board with SOC 1052 with group 1054 and group 1056, each being groups of CAMMs. Second row 1004 has a sixth interposer board with SOC 1062 with group 1064 and group 1066, each being groups of CAMMs. Second row 1004 has a seventh interposer board with SOC 1072 with group 1074 and group 1076, each being groups of CAMMs. Second row 1004 has an eighth interposer board with SOC 1082 with group 1084 and group 1086, each being groups of CAMMs.

In both system 900 of FIG. 9 and system 1000 of FIG. 10, the system illustrates system boards with SOCs and memory modules that are coupled together on a single baseboard, as opposed to being different nodes in different server racks. In one example, system 900 and system 1000 have 1U configurations, which fit in a single rack space of a server rack. In one example, either system 900 or system 1000 has a 2U configuration, which requires two rack spaces of a server rack.

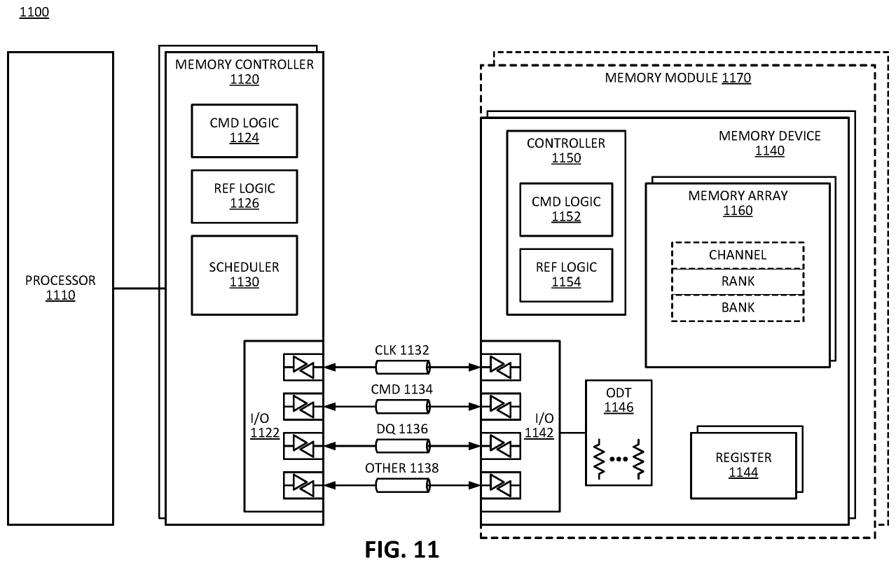

FIG. 11 is a block diagram of an example of a memory subsystem in which a high density memory configuration can be implemented. System 1100 includes a processor and elements of a memory subsystem in a computing device. System 1100 is an example of a system in accordance with an example of system 100.

In one example, memory module 1170 is a compression-attached memory module. In one example, processor 1110 and memory controller 1120 are part of a system on a chip. In one example, processor 1110 represents multiple processors each with multiple memory subsystems on an interposer board. The interposer board can have processor devices with multiple memory channels from multiple memory modules. In one example, the system has a thermal solution that sits atop the processor and its multiple memory modules.

Processor 1110 represents a processing unit of a computing platform that may execute an operating system (OS) and applications, which can collectively be referred to as the host or the user of the memory. The OS and applications execute operations that result in memory accesses. Processor 1110 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory accesses may also be initiated by devices such as a network controller or hard disk controller. Such devices can be integrated with the processor in some systems or attached to the processer via a bus (e.g., PCI express), or a combination. System 1100 can be implemented as an SOC (system on a chip), or be implemented with standalone components.

Reference to memory devices can apply to different memory types. Memory devices often refers to volatile memory technologies. Volatile memory is memory whose state (and therefore the data stored on it) is indeterminate if power is interrupted to the device. Nonvolatile memory refers to memory whose state is determinate even if power is interrupted to the device. Dynamic volatile memory requires refreshing the data stored in the device to maintain state. One example of dynamic volatile memory includes DRAM (dynamic random-access memory), or some variant such as synchronous DRAM (SDRAM). A memory subsystem as described herein may be compatible with a number of memory technologies, such as DDR4 (double data rate version 4, JESD79-4, originally published in September 2012 by JEDEC (Joint Electron Device Engineering Council, now the JEDEC Solid State Technology Association), LPDDR4 (low power DDR version 4, JESD209-4, originally published by JEDEC in August 2014), WIO2 (Wide I/O 2 (WideIO2), JESD229-2, originally published by JEDEC in August 2014), HBM (high bandwidth memory DRAM, JESD235A, originally published by JEDEC in November 2015), DDR5 (DDR version 5, originally published by JEDEC in July 2020), LPDDR5 (LPDDR version 5, JESD209-5, originally published by JEDEC in February 2019), HBM2 (HBM version 2, JESD235C, originally published by JEDEC in January 2020), HBM3 (HBM version 3, JESD238, originally published by JEDEC in January 2022), DDR6 (DDR version 6, currently in discussion by JEDEC), or others or combinations of memory technologies, and technologies based on derivatives or extensions of such specifications.

Memory controller 1120 represents one or more memory controller circuits or devices for system 1100. Memory controller 1120 represents control logic that generates memory access commands in response to the execution of operations by processor 1110. Memory controller 1120 accesses one or more memory devices 1140. Memory devices 1140 can be DRAM devices in accordance with any referred to above. In one example, memory devices 1140 are organized and managed as different channels, where each channel couples to buses and signal lines that couple to multiple memory devices in parallel. Each channel is independently operable. Thus, each channel is independently accessed and controlled, and the timing, data transfer, command and address exchanges, and other operations are separate for each channel. Coupling can refer to an electrical coupling, communicative coupling, physical coupling, or a combination of these. Physical coupling can include direct contact. Electrical coupling includes an interface or interconnection that allows electrical flow between components, or allows signaling between components, or both. Communicative coupling includes connections, including wired or wireless, that enable components to exchange data.

In one example, settings for each channel are controlled by separate mode registers or other register settings. In one example, each memory controller 1120 manages a separate memory channel, although system 1100 can be configured to have multiple channels managed by a single controller, or to have multiple controllers on a single channel. In one example, memory controller 1120 is part of host processor 1110, such as logic implemented on the same die or implemented in the same package space as the processor.

Memory controller 1120 includes I/O interface logic 1122 to couple to a memory bus, such as a memory channel as referred to above. I/O interface logic 1122 (as well as I/O interface logic 1142 of memory device 1140) can include pins, pads, connectors, signal lines, traces, or wires, or other hardware to connect the devices, or a combination of these. I/O interface logic 1122 can include a hardware interface. As illustrated, I/O interface logic 1122 includes at least drivers/transceivers for signal lines. Commonly, wires within an integrated circuit interface couple with a pad, pin, or connector to interface signal lines or traces or other wires between devices. I/O interface logic 1122 can include drivers, receivers, transceivers, or termination, or other circuitry or combinations of circuitry to exchange signals on the signal lines between the devices. The exchange of signals includes at least one of transmit or receive. While shown as coupling I/O 1122 from memory controller 1120 to I/O 1142 of memory device 1140, it will be understood that in an implementation of system 1100 where groups of memory devices 1140 are accessed in parallel, multiple memory devices can include I/O interfaces to the same interface of memory controller 1120. In an implementation of system 1100 including one or more memory modules 1170, I/O 1142 can include interface hardware of the memory module in addition to interface hardware on the memory device itself. Other memory controllers 1120 will include separate interfaces to other memory devices 1140.

The bus between memory controller 1120 and memory devices 1140 can be implemented as multiple signal lines coupling memory controller 1120 to memory devices 1140. The bus may typically include at least clock (CLK) 1132, command/address (CMD) 1134, and write data (DQ) and read data (DQ) 1136, and zero or more other signal lines 1138. In one example, a bus or connection between memory controller 1120 and memory can be referred to as a memory bus. In one example, the memory bus is a multi-drop bus. The signal lines for CMD can be referred to as a “C/A bus” (or ADD/CMD bus, or some other designation indicating the transfer of commands (C or CMD) and address (A or ADD) information) and the signal lines for write and read DQ can be referred to as a “data bus.” In one example, independent channels have different clock signals, C/A buses, data buses, and other signal lines. Thus, system 1100 can be considered to have multiple “buses,” in the sense that an independent interface path can be considered a separate bus. It will be understood that in addition to the lines explicitly shown, a bus can include at least one of strobe signaling lines, alert lines, auxiliary lines, or other signal lines, or a combination. It will also be understood that serial bus technologies can be used for the connection between memory controller 1120 and memory devices 1140. An example of a serial bus technology is 8B10B encoding and transmission of high-speed data with embedded clock over a single differential pair of signals in each direction. In one example, CMD 1134 represents signal lines shared in parallel with multiple memory devices. In one example, multiple memory devices share encoding command signal lines of CMD 1134, and each has a separate chip select (CS_n) signal line to select individual memory devices.

It will be understood that in the example of system 1100, the bus between memory controller 1120 and memory devices 1140 includes a subsidiary command bus CMD 1134 and a subsidiary bus to carry the write and read data, DQ 1136. In one example, the data bus can include bidirectional lines for read data and for write/command data. In another example, the subsidiary bus DQ 1136 can include unidirectional write signal lines for write and data from the host to memory, and can include unidirectional lines for read data from the memory to the host. In accordance with the chosen memory technology and system design, other signals 1138 may accompany a bus or sub bus, such as strobe lines DQS. Based on design of system 1100, or implementation if a design supports multiple implementations, the data bus can have more or less bandwidth per memory device 1140. For example, the data bus can support memory devices that have either a x4 interface, a x8 interface, a x16 interface, or other interface. The convention “xW,” where W is an integer that refers to an interface size or width of the interface of memory device 1140, which represents a number of signal lines to exchange data with memory controller 1120. The interface size of the memory devices is a controlling factor on how many memory devices can be used concurrently per channel in system 1100 or coupled in parallel to the same signal lines. In one example, high bandwidth memory devices, wide interface devices, or stacked memory configurations, or combinations, can enable wider interfaces, such as a x128 interface, a x256 interface, a x512 interface, a x1024 interface, or other data bus interface width.

In one example, memory devices 1140 and memory controller 1120 exchange data over the data bus in a burst, or a sequence of consecutive data transfers. The burst corresponds to a number of transfer cycles, which is related to a bus frequency. In one example, the transfer cycle can be a whole clock cycle for transfers occurring on a same clock or strobe signal edge (e.g., on the rising edge). In one example, every clock cycle, referring to a cycle of the system clock, is separated into multiple unit intervals (UIs), where each UI is a transfer cycle. For example, double data rate transfers trigger on both edges of the clock signal (e.g., rising and falling). A burst can last for a configured number of UIs, which can be a configuration stored in a register, or triggered on the fly. For example, a sequence of eight consecutive transfer periods can be considered a burst length eight (BL8), and each memory device 1140 can transfer data on each UI. Thus, a x8 memory device operating on BL8 can transfer 64 bits of data (8 data signal lines times 8 data bits transferred per line over the burst). It will be understood that this simple example is merely an illustration and is not limiting.

Memory devices 1140 represent memory resources for system 1100. In one example, each memory device 1140 is a separate memory die. In one example, each memory device 1140 can interface with multiple (e.g., 2) channels per device or die. Each memory device 1140 includes I/O interface logic 1142, which has a bandwidth determined by the implementation of the device (e.g., x16 or x8 or some other interface bandwidth). I/O interface logic 1142 enables the memory devices to interface with memory controller 1120. I/O interface logic 1142 can include a hardware interface, and can be in accordance with I/O 1122 of memory controller, but at the memory device end. In one example, multiple memory devices 1140 are connected in parallel to the same command and data buses. In another example, multiple memory devices 1140 are connected in parallel to the same command bus, and are connected to different data buses. For example, system 1100 can be configured with multiple memory devices 1140 coupled in parallel, with each memory device responding to a command, and accessing memory resources 1160 internal to each. For a Write operation, an individual memory device 1140 can write a portion of the overall data word, and for a Read operation, an individual memory device 1140 can fetch a portion of the overall data word. The remaining bits of the word will be provided or received by other memory devices in parallel.

In one example, memory devices 1140 are disposed directly on a motherboard or host system platform (e.g., a PCB (printed circuit board) or substrate on which processor 1110 is disposed) of a computing device. In one example, memory devices 1140 can be organized into memory modules 1170. In one example, memory modules 1170 represent dual inline memory modules (DIMMs). In one example, memory modules 1170 represent other organization of multiple memory devices to share at least a portion of access or control circuitry, which can be a separate circuit, a separate device, or a separate board from the host system platform. Memory modules 1170 can include multiple memory devices 1140, and the memory modules can include support for multiple separate channels to the included memory devices disposed on them. In another example, memory devices 1140 may be incorporated into the same package as memory controller 1120, such as by techniques such as multi-chip-module (MCM), package-on-package, through-silicon via (TSV), or other techniques or combinations. Similarly, in one example, multiple memory devices 1140 may be incorporated into memory modules 1170, which themselves may be incorporated into the same package as memory controller 1120. It will be appreciated that for these and other implementations, memory controller 1120 may be part of host processor 1110.

Memory devices 1140 each include one or more memory arrays 1160. Memory array 1160 represents addressable memory locations or storage locations for data. Typically, memory array 1160 is managed as rows of data, accessed via wordline (rows) and bitline (individual bits within a row) control. Memory array 1160 can be organized as separate channels, ranks, and banks of memory. Channels may refer to independent control paths to storage locations within memory devices 1140. Ranks may refer to common locations across multiple memory devices (e.g., same row addresses within different devices) in parallel. Banks may refer to sub-arrays of memory locations within a memory device 1140. In one example, banks of memory are divided into sub-banks with at least a portion of shared circuitry (e.g., drivers, signal lines, control logic) for the sub-banks, allowing separate addressing and access. It will be understood that channels, ranks, banks, sub-banks, bank groups, or other organizations of the memory locations, and combinations of the organizations, can overlap in their application to physical resources. For example, the same physical memory locations can be accessed over a specific channel as a specific bank, which can also belong to a rank. Thus, the organization of memory resources will be understood in an inclusive, rather than exclusive, manner.

In one example, memory devices 1140 include one or more registers 1144. Register 1144 represents one or more storage devices or storage locations that provide configuration or settings for the operation of the memory device. In one example, register 1144 can provide a storage location for memory device 1140 to store data for access by memory controller 1120 as part of a control or management operation. In one example, register 1144 includes one or more Mode Registers. In one example, register 1144 includes one or more multipurpose registers. The configuration of locations within register 1144 can configure memory device 1140 to operate in different “modes,” where command information can trigger different operations within memory device 1140 based on the mode. Additionally or in the alternative, different modes can also trigger different operation from address information or other signal lines depending on the mode. Settings of register 1144 can indicate configuration for I/O settings (e.g., timing, termination or ODT (on-die termination) 1146, driver configuration, or other I/O settings).

In one example, memory device 1140 includes ODT 1146 as part of the interface hardware associated with I/O 1142. ODT 1146 can be configured as mentioned above, and provide settings for impedance to be applied to the interface to specified signal lines. In one example, ODT 1146 is applied to DQ signal lines. In one example, ODT 1146 is applied to command signal lines. In one example, ODT 1146 is applied to address signal lines. In one example, ODT 1146 can be applied to any combination of the preceding. The ODT settings can be changed based on whether a memory device is a selected target of an access operation or a non-target device. ODT 1146 settings can affect the timing and reflections of signaling on the terminated lines. Careful control over ODT 1146 can enable higher-speed operation with improved matching of applied impedance and loading. ODT 1146 can be applied to specific signal lines of I/O interface 1142, 1122 (for example, ODT for DQ lines or ODT for CA lines), and is not necessarily applied to all signal lines.

Memory device 1140 includes controller 1150, which represents control logic within the memory device to control internal operations within the memory device. For example, controller 1150 decodes commands sent by memory controller 1120 and generates internal operations to execute or satisfy the commands. Controller 1150 can be referred to as an internal controller, and is separate from memory controller 1120 of the host. Controller 1150 can determine what mode is selected based on register 1144, and configure the internal execution of operations for access to memory resources 1160 or other operations based on the selected mode. Controller 1150 generates control signals to control the routing of bits within memory device 1140 to provide a proper interface for the selected mode and direct a command to the proper memory locations or addresses. Controller 1150 includes command logic 1152, which can decode command encoding received on command and address signal lines. Thus, command logic 1152 can be or include a command decoder. With command logic 1152, memory device can identify commands and generate internal operations to execute requested commands.

Referring again to memory controller 1120, memory controller 1120 includes command (CMD) logic 1124, which represents logic or circuitry to generate commands to send to memory devices 1140. The generation of the commands can refer to the command prior to scheduling, or the preparation of queued commands ready to be sent. Generally, the signaling in memory subsystems includes address information within or accompanying the command to indicate or select one or more memory locations where the memory devices should execute the command. In response to scheduling of transactions for memory device 1140, memory controller 1120 can issue commands via I/O 1122 to cause memory device 1140 to execute the commands. In one example, controller 1150 of memory device 1140 receives and decodes command and address information received via I/O 1142 from memory controller 1120. Based on the received command and address information, controller 1150 can control the timing of operations of the logic and circuitry within memory device 1140 to execute the commands. Controller 1150 is responsible for compliance with standards or specifications within memory device 1140, such as timing and signaling requirements. Memory controller 1120 can implement compliance with standards or specifications by access scheduling and control.

Memory controller 1120 includes scheduler 1130, which represents logic or circuitry to generate and order transactions to send to memory device 1140. From one perspective, the primary function of memory controller 1120 could be said to schedule memory access and other transactions to memory device 1140. Such scheduling can include generating the transactions themselves to implement the requests for data by processor 1110 and to maintain integrity of the data (e.g., such as with commands related to refresh). Transactions can include one or more commands, and result in the transfer of commands or data or both over one or multiple timing cycles such as clock cycles or unit intervals. Transactions can be for access such as read or write or related commands or a combination, and other transactions can include memory management commands for configuration, settings, data integrity, or other commands or a combination.

Memory controller 1120 typically includes logic such as scheduler 1130 to allow selection and ordering of transactions to improve performance of system 1100. Thus, memory controller 1120 can select which of the outstanding transactions should be sent to memory device 1140 in which order, which is typically achieved with logic much more complex that a simple first-in first-out algorithm. Memory controller 1120 manages the transmission of the transactions to memory device 1140, and manages the timing associated with the transaction. In one example, transactions have deterministic timing, which can be managed by memory controller 1120 and used in determining how to schedule the transactions with scheduler 1130.

In one example, memory controller 1120 includes refresh (REF) logic 1126. Refresh logic 1126 can be used for memory resources that are volatile and need to be refreshed to retain a deterministic state. In one example, refresh logic 1126 indicates a location for refresh, and a type of refresh to perform. Refresh logic 1126 can trigger self-refresh within memory device 1140, or execute external refreshes which can be referred to as auto refresh commands) by sending refresh commands, or a combination. In one example, controller 1150 within memory device 1140 includes refresh logic 1154 to apply refresh within memory device 1140. In one example, refresh logic 1154 generates internal operations to perform refresh in accordance with an external refresh received from memory controller 1120. Refresh logic 1154 can determine if a refresh is directed to memory device 1140, and what memory resources 1160 to refresh in response to the command.

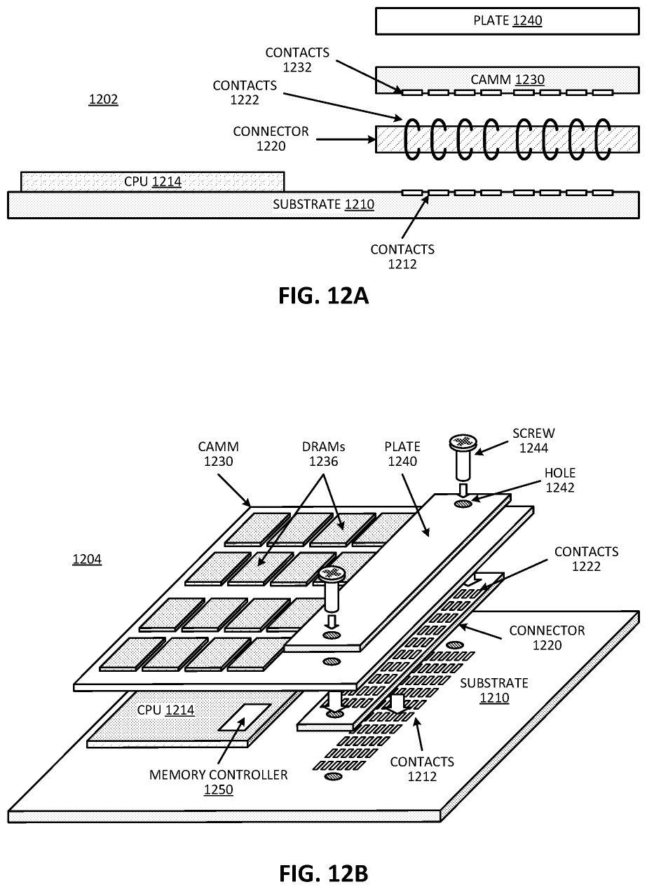

FIGS. 12A-12B are block diagrams of an example of a CAMM system for a high density memory configuration.

Referring to FIG. 12A, system 1202 includes a memory stack architecture monitored by a memory fault tracker that can perform mirroring. System 1202 is an example of a system in accordance with an example of system 100.

Substrate 1210 illustrates an SOC package substrate or a motherboard or system board. Substrate 1210 includes contacts 1212, which represent contacts for connecting with memory. CPU 1214 represents a processor or central processing unit (CPU) chip or graphics processing unit (GPU) chip to be disposed on substrate 1210. CPU 1214 performs the computational operations in system 1202. In one example, CPU 1214 includes multiple cores (not specifically shown), which can generate operations that request data to be read from and written to memory. CPU 1214 can include a memory controller to manage access to the memory devices.

Compression-attached memory module (CAMM) 1230 represents a module with memory devices, which are not specifically illustrated in system 1202. Substrate 1210 couples to CAMM 1230 and its memory devices through compression mount technology (CMT) connector 1220. Connector 1220 includes contacts 1222, which are compression-based contacts. The compression-based contacts are compressible pins or devices whose shape compresses with the application of pressure on connector 1220. In one example, contacts 1222 represent C-shaped pins as illustrated. In one example, contacts 1222 represent another compressible pin shape, such as a spring-shape, an S-shape, or pins having other shapes that can be compressed.

CAMM 1230 includes contacts 1232 on a side of the CAMM board that interfaces with connector 1220. Contacts 1232 connect to memory devices on the CAMM board. Plate 1240 represents a plate or housing that provides structure to apply pressure to compress contacts 1222 of connector 1220.

Referring to FIG. 12B, system 1204 is a perspective view of a system in accordance with system 1202. System 1204 illustrates memory controller 1250, which is not specifically illustrated in system 1202. CAMM 1230 is illustrated with memory chips or memory dies, identified as DRAMs 1236 on one or both faces of the PCB of CAMM 1230. In a client device implementation, DRAMs 1236 can be on either face of the PCB. In a server implementation, DRAMs 1236 will be only on one face of the PCB to manage power density. DRAMs 1236 are coupled with conductive contacts via conductive traces in or on the PCB, which couples with contacts 1232, which in turn couple with contacts 1222 of connector 1220.

System 1204 illustrates holes 1242 in plate 1240 to receive fasteners, represented by screws 1244. There are corresponding holes through CAMM 1230, connector 1220, and in substrate 1210. Screws 1244 can compressibly attach the CAMM 1230 to substrate 1210 via connector 1220.

System 1202 and system 1202 can represent CAMM devices for a system with multiple memory modules coupled to a processor on an interposer board, in accordance with any description herein.

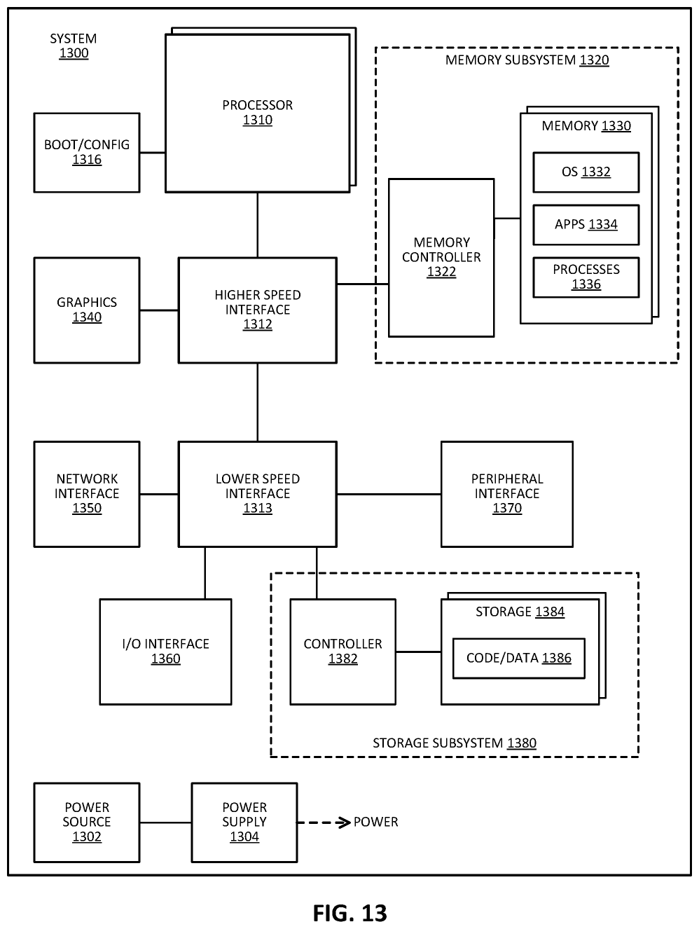

FIG. 13 is a block diagram of an example of a computing system in which a high density memory configuration can be implemented. System 1300 represents a computing device in accordance with any example herein, and can be a laptop computer, a desktop computer, a tablet computer, a server, a gaming or entertainment control system, embedded computing device, or other electronic device.

System 1300 is an example of a system in accordance with an example of system 100. In one example, memory subsystem 1320 is implemented with compression-attached memory modules. In one example, processor 1310 and memory controller 1322 are part of a system on a chip. In one example, processor 1310 represents multiple processors each with multiple memory subsystems on an interposer board. The interposer board can have processor devices with multiple memory channels from multiple memory modules. In one example, the system has a thermal solution that sits atop the processor and its multiple memory modules.

System 1300 includes processor 1310 can include any type of microprocessor, central processing unit (CPU), graphics processing unit (GPU), processing core, or other processing hardware, or a combination, to provide processing or execution of instructions for system 1300. Processor 1310 can be a host processor device. Processor 1310 controls the overall operation of system 1300, and can be or include, one or more programmable general-purpose or special-purpose microprocessors, digital signal processors (DSPs), programmable controllers, application specific integrated circuits (ASICs), programmable logic devices (PLDs), or a combination of such devices.

System 1300 includes boot/config 1316, which represents storage to store boot code (e.g., basic input/output system (BIOS)), configuration settings, security hardware (e.g., trusted platform module (TPM)), or other system level hardware that operates outside of a host OS. Boot/config 1316 can include a nonvolatile storage device, such as read-only memory (ROM), flash memory, or other memory devices.

In one example, system 1300 includes interface 1312 coupled to processor 1310, which can represent a higher speed interface or a high throughput interface for system components that need higher bandwidth connections, such as memory subsystem 1320 or graphics interface components 1340. Interface 1312 represents an interface circuit, which can be a standalone component or integrated onto a processor die. Interface 1312 can be integrated as a circuit onto the processor die or integrated as a component on a system on a chip. Where present, graphics interface 1340 interfaces to graphics components for providing a visual display to a user of system 1300. Graphics interface 1340 can be a standalone component or integrated onto the processor die or system on a chip. In one example, graphics interface 1340 can drive a high definition (HD) display or ultra high definition (UHD) display that provides an output to a user. In one example, the display can include a touchscreen display. In one example, graphics interface 1340 generates a display based on data stored in memory 1330 or based on operations executed by processor 1310 or both.

Memory subsystem 1320 represents the main memory of system 1300, and provides storage for code to be executed by processor 1310, or data values to be used in executing a routine. Memory subsystem 1320 can include one or more varieties of random-access memory (RAM) such as DRAM, 3DXP (three-dimensional crosspoint), or other memory devices, or a combination of such devices. Memory 1330 stores and hosts, among other things, operating system (OS) 1332 to provide a software platform for execution of instructions in system 1300. Additionally, applications 1334 can execute on the software platform of OS 1332 from memory 1330. Applications 1334 represent programs that have their own operational logic to perform execution of one or more functions. Processes 1336 represent agents or routines that provide auxiliary functions to OS 1332 or one or more applications 1334 or a combination. OS 1332, applications 1334, and processes 1336 provide software logic to provide functions for system 1300. In one example, memory subsystem 1320 includes memory controller 1322, which is a memory controller to generate and issue commands to memory 1330. It will be understood that memory controller 1322 could be a physical part of processor 1310 or a physical part of interface 1312. For example, memory controller 1322 can be an integrated memory controller, integrated onto a circuit with processor 1310, such as integrated onto the processor die or a system on a chip.

While not specifically illustrated, it will be understood that system 1300 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a HyperTransport or industry standard architecture (ISA) bus, a small computer system interface (SCSI) bus, a universal serial bus (USB), or other bus, or a combination.

In one example, system 1300 includes interface 1314, which can be coupled to interface 1312. Interface 1314 can be a lower speed interface than interface 1312. In one example, interface 1314 represents an interface circuit, which can include standalone components and integrated circuitry. In one example, multiple user interface components or peripheral components, or both, couple to interface 1314. Network interface 1350 provides system 1300 the ability to communicate with remote devices (e.g., servers or other computing devices) over one or more networks. Network interface 1350 can include an Ethernet adapter, wireless interconnection components, cellular network interconnection components, USB (universal serial bus), or other wired or wireless standards-based or proprietary interfaces. Network interface 1350 can exchange data with a remote device, which can include sending data stored in memory or receiving data to be stored in memory.

In one example, system 1300 includes one or more input/output (I/O) interface(s) 1360. I/O interface 1360 can include one or more interface components through which a user interacts with system 1300 (e.g., audio, alphanumeric, tactile/touch, or other interfacing). Peripheral interface 1370 can include any hardware interface not specifically mentioned above. Peripherals refer generally to devices that connect dependently to system 1300. A dependent connection is one where system 1300 provides the software platform or hardware platform or both on which operation executes, and with which a user interacts.

In one example, system 1300 includes storage subsystem 1380 to store data in a nonvolatile manner. In one example, in certain system implementations, at least certain components of storage 1380 can overlap with components of memory subsystem 1320. Storage subsystem 1380 includes storage device(s) 1384, which can be or include any conventional medium for storing large amounts of data in a nonvolatile manner, such as one or more magnetic, solid state, NAND, 3DXP, or optical based disks, or a combination. Storage 1384 holds code or instructions and data 1386 in a persistent state (i.e., the value is retained despite interruption of power to system 1300). Storage 1384 can be generically considered to be a “memory,” although memory 1330 is typically the executing or operating memory to provide instructions to processor 1310. Whereas storage 1384 is nonvolatile, memory 1330 can include volatile memory (i.e., the value or state of the data is indeterminate if power is interrupted to system 1300). In one example, storage subsystem 1380 includes controller 1382 to interface with storage 1384. In one example controller 1382 is a physical part of interface 1314 or processor 1310, or can include circuits or logic in both processor 1310 and interface 1314.

Power source 1302 provides power to the components of system 1300. More specifically, power source 1302 typically interfaces to one or multiple power supplies 1304 in system 1300 to provide power to the components of system 1300. In one example, power supply 1304 includes an AC to DC (alternating current to direct current) adapter to plug into a wall outlet. Such AC power can be renewable energy (e.g., solar power) power source 1302. In one example, power source 1302 includes a DC power source, such as an external AC to DC converter. In one example, power source 1302 or power supply 1304 includes wireless charging hardware to charge via proximity to a charging field. In one example, power source 1302 can include an internal battery or fuel cell source.

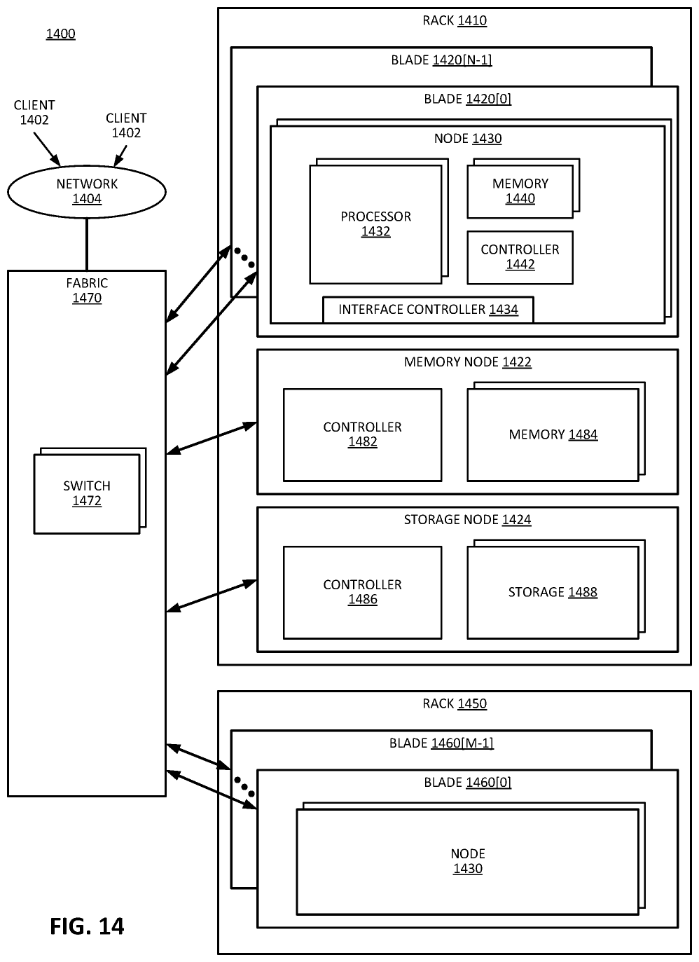

FIG. 14 is a block diagram of an example of a multi-node network in which a high density memory configuration can be implemented. In one example, system 1400 represents a data center. In one example, system 1400 represents a server farm. In one example, system 1400 represents a data cloud or a processing cloud.

Nodes 1430 of system 1400 represent a system in accordance with an example of system 100. In one example, node 1430 includes memory 1440, which can be implemented with compression-attached memory modules. In one example, processor 1432 and controller 1442 are part of a system on a chip. In one example, processor 1432 represents multiple processors each with multiple memory subsystems on an interposer board. The interposer board can have processor devices with multiple memory channels from multiple memory modules. In one example, the system has a thermal solution that sits atop the processor and its multiple memory modules.

One or more clients 1402 make requests over network 1404 to system 1400. Network 1404 represents one or more local networks, or wide area networks, or a combination. Clients 1402 can be human or machine clients, which generate requests for the execution of operations by system 1400. System 1400 executes applications or data computation tasks requested by clients 1402.

In one example, system 1400 includes one or more racks, which represent structural and interconnect resources to house and interconnect multiple computation nodes. In one example, rack 1410 includes multiple nodes 1430. In one example, rack 1410 hosts multiple blade components, blade 1420[0], . . . , blade 1420[N−1], collectively blades 1420. Hosting refers to providing power, structural or mechanical support, and interconnection. Blades 1420 can refer to computing resources on printed circuit boards (PCBs), where a PCB houses the hardware components for one or more nodes 1430. In one example, blades 1420 do not include a chassis or housing or other “box” other than that provided by rack 1410. In one example, blades 1420 include housing with exposed connector to connect into rack 1410. In one example, system 1400 does not include rack 1410, and each blade 1420 includes a chassis or housing that can stack or otherwise reside in close proximity to other blades and allow interconnection of nodes 1430.

System 1400 includes fabric 1470, which represents one or more interconnectors for nodes 1430. In one example, fabric 1470 includes multiple switches 1472 or routers or other hardware to route signals among nodes 1430. Additionally, fabric 1470 can couple system 1400 to network 1404 for access by clients 1402. In addition to routing equipment, fabric 1470 can be considered to include the cables or ports or other hardware equipment to couple nodes 1430 together. In one example, fabric 1470 has one or more associated protocols to manage the routing of signals through system 1400. In one example, the protocol or protocols is at least partly dependent on the hardware equipment used in system 1400.

As illustrated, rack 1410 includes N blades 1420. In one example, in addition to rack 1410, system 1400 includes rack 1450. As illustrated, rack 1450 includes M blade components, blade 1460[0], . . . , blade 1460[M−1], collectively blades 1460. M is not necessarily the same as N; thus, it will be understood that various different hardware equipment components could be used, and coupled together into system 1400 over fabric 1470. Blades 1460 can be the same or similar to blades 1420. Nodes 1430 can be any type of node and are not necessarily all the same type of node. System 1400 is not limited to being homogenous, nor is it limited to not being homogenous.

The nodes in system 1400 can include compute nodes, memory nodes, storage nodes, accelerator nodes, or other nodes. Rack 1410 is represented with memory node 1422 and storage node 1424, which represent shared system memory resources, and shared persistent storage, respectively. One or more nodes of rack 1450 can be a memory node or a storage node.

Nodes 1430 represent examples of compute nodes. For simplicity, only the compute node in blade 1420[0] is illustrated in detail. However, other nodes in system 1400 can be the same or similar. At least some nodes 1430 are computation nodes, with processor (proc) 1432 and memory 1440. A computation node refers to a node with processing resources (e.g., one or more processors) that executes an operating system and can receive and process one or more tasks. In one example, at least some nodes 1430 are server nodes with a server as processing resources represented by processor 1432 and memory 1440.

Memory node 1422 represents an example of a memory node, with system memory external to the compute nodes. Memory nodes can include controller 1482, which represents a processor on the node to manage access to the memory. The memory nodes include memory 1484 as memory resources to be shared among multiple compute nodes.

Storage node 1424 represents an example of a storage server, which refers to a node with more storage resources than a computation node, and rather than having processors for the execution of tasks, a storage server includes processing resources to manage access to the storage nodes within the storage server. Storage nodes can include controller 1486 to manage access to the storage 1488 of the storage node.

In one example, node 1430 includes interface controller 1434, which represents logic to control access by node 1430 to fabric 1470. The logic can include hardware resources to interconnect to the physical interconnection hardware. The logic can include software or firmware logic to manage the interconnection. In one example, interface controller 1434 is or includes a host fabric interface, which can be a fabric interface in accordance with any example described herein. The interface controllers for memory node 1422 and storage node 1424 are not explicitly shown.

Processor 1432 can include one or more separate processors. Each separate processor can include a single processing unit, a multicore processing unit, or a combination. The processing unit can be a primary processor such as a CPU (central processing unit), a peripheral processor such as a GPU (graphics processing unit), or a combination. Memory 1440 can be or include memory devices represented by memory 1440 and a memory controller represented by controller 1442.

In general with respect to the descriptions herein, in one example, an apparatus includes: a printed circuit board (PCB); a processor device mounted to the PCB; and multiple compression attached memory modules (CAMMs) removably attached to the PCB around the processor device, the CAMMs to provide multiple memory channels for the processor device, the multiple memory channels to provide memory access independent of each other.

In one example of the apparatus, the multiple CAMMs are all mounted on a same side of the PCB as the processor device. In accordance with any preceding example, in one example, the multiple CAMMs surround all sides of the processor device. In accordance with any preceding example, in one example, the multiple CAMMs are mounted both on a same side of the PCB as the processor device and on a side of the PCB opposite the processor device. In accordance with any preceding example, in one example, each of the multiple CAMMs has multiple memory channels. In accordance with any preceding example, in one example, the apparatus includes: a single thermal plate to cover and disperse heat from the processor device and the multiple CAMMs. In accordance with any preceding example, in one example, the processor device comprises a central processing unit (CPU). In accordance with any preceding example, in one example, the processor device comprises a graphics processing unit (GPU). In accordance with any preceding example, in one example, the PCB comprises an interposer circuit board.

In general with respect to the descriptions herein, in one example, a system includes: a system board; chipset circuitry disposed on the system board, the chipset circuitry providing interface to peripheral devices; and an interposer board mounted on the system board and electrically coupled to the chipset circuitry, the interposer board including: a processor device mounted to the interposer board; and multiple compression attached memory modules (CAMMs) removably attached to the interposer board around the processor device, the CAMMs to provide multiple memory channels for the processor device, the multiple memory channels to provide memory access independent of each other.

In one example of the system, each of the multiple CAMMs has multiple memory channels. In accordance with any preceding example, in one example, the system includes: a single thermal plate for the interposer board, to cover and disperse heat from the processor device and the multiple CAMMs. In accordance with any preceding example, in one example, the processor device comprises a central processing unit (CPU) or a graphics processing unit (GPU). In accordance with any preceding example, in one example, the interposer board is mounted on the system board in a socket connector. In accordance with any preceding example, in one example, the interposer board is mounted to the system board without a socket connector. In accordance with any preceding example, in one example, the interposer board is mounted to the system board via a mezzanine connector. In accordance with any preceding example, in one example, the interposer board comprises a first interposer board, the processor device comprises a first processor device, and the multiple CAMMs comprise first multiple CAMMs, and further comprising a second interposer board with a second processor device and second multiple CAMMs, the second interposer board mounted on a same side of the system board as first interposer board. In accordance with any preceding example, in one example, the interposer board comprises a first interposer board, the processor device comprises a first processor device, and the multiple CAMMs comprise first multiple CAMMs, and further comprising a second interposer board with a second processor device and second multiple CAMMs. In accordance with any preceding example, in one example, the first interposer board is on a front side of the system board, and the second interposer board is on a back side of the system board. In accordance with any preceding example, in one example, the processor device comprises a multicore processor. In accordance with any preceding example, in one example, the system includes a display communicatively coupled to the processor device. In accordance with any preceding example, in one example, the system includes a battery to power the system. In accordance with any preceding example, in one example, the chipset circuitry comprises a network interface circuit to couple with a remote device over a network connection.

Flow diagrams as illustrated herein provide examples of sequences of various process actions. The flow diagrams can indicate operations to be executed by a software or firmware routine, as well as physical operations. A flow diagram can illustrate an example of the implementation of states of a finite state machine (FSM), which can be implemented in hardware and/or software. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted; thus, not all implementations will perform all actions.

To the extent various operations or functions are described herein, they can be described or defined as software code, instructions, configuration, and/or data. The content can be directly executable (“object” or “executable” form), source code, or difference code (“delta” or “patch” code). The software content of what is described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware, application specific integrated circuits (ASICs), digital signal processors (DSPs), etc.), embedded controllers, hardwired circuitry, etc.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. An apparatus comprising:
a printed circuit board (PCB);
a processor device mounted to the PCB; and
multiple compression attached memory modules (CAMMs) removably attached to the PCB around the processor device, the CAMMs to provide multiple memory channels for the processor device, the multiple memory channels to provide memory access independent of each other.

2. The apparatus of claim 1, wherein the multiple CAMMs are all mounted on a same side of the PCB as the processor device.

3. The apparatus of claim 1, wherein the multiple CAMMs surround all sides of the processor device.

4. The apparatus of claim 1, wherein the multiple CAMMs are mounted both on a same side of the PCB as the processor device and on a side of the PCB opposite the processor device.

5. The apparatus of claim 1, wherein each of the multiple CAMMs has multiple memory channels.

6. The apparatus of claim 1, further comprising:
a single thermal plate to cover and disperse heat from the processor device and the multiple CAMMs.

7. The apparatus of claim 1, wherein the processor device comprises a central processing unit (CPU).

8. The apparatus of claim 1, wherein the processor device comprises a graphics processing unit (GPU).

9. The apparatus of claim 1, wherein the PCB comprises an interposer circuit board.

10. A system comprising:
a system board;
chipset circuitry disposed on the system board, the chipset circuitry providing interface to peripheral devices; and
an interposer board mounted on the system board and electrically coupled to the chipset circuitry, the interposer board including:
a processor device mounted to the interposer board; and
multiple compression attached memory modules (CAMMs) removably attached to the interposer board around the processor device, the CAMMs to provide multiple memory channels for the processor device, the multiple memory channels to provide memory access independent of each other.

11. The system of claim 10, wherein each of the multiple CAMMs has multiple memory channels.

12. The system of claim 10, further comprising:
a single thermal plate for the interposer board, to cover and disperse heat from the processor device and the multiple CAMMs.

13. The system of claim 10, wherein the processor device comprises a central processing unit (CPU) or a graphics processing unit (GPU).

14. The system of claim 10, wherein the interposer board is mounted on the system board in a socket connector.

15. The system of claim 10, wherein the interposer board is mounted to the system board without a socket connector.

16. The system of claim 15, wherein the interposer board is mounted to the system board via a mezzanine connector.

17. The system of claim 10, wherein the interposer board comprises a first interposer board, the processor device comprises a first processor device, and the multiple CAMMs comprise first multiple CAMMs, and further comprising a second interposer board with a second processor device and second multiple CAMMs, the second interposer board mounted on a same side of the system board as first interposer board.

18. The system of claim 10, wherein the interposer board comprises a first interposer board, the processor device comprises a first processor device, and the multiple CAMMs comprise first multiple CAMMs, and further comprising a second interposer board with a second processor device and second multiple CAMMs.

19. The system of claim 10,
wherein the processor device comprises a multicore processor;
further comprising a display communicatively coupled to the processor device;
further comprising a battery to power the system; or
wherein the chipset circuitry comprises a network interface circuit to couple with a remote device over a network connection.
